(19) United States
(12) Patent Application Publication
(10) Pub. No.: US 2025/0208219 A1
(43) Pub. Date: Jun. 26, 2025

(54) SECONDARY BATTERY CHARACTERISTIC ACQUISITION SYSTEM AND SECONDARY BATTERY CHARACTERISTIC ACQUISITION METHOD

(71) Applicant: MURATA MANUFACTURING CO., LTD., Kyoto (JP)

(72) Inventors: Koji HATTORI, Kyoto (JP); Asuki YANAGIHARA, Kyoto (JP); Fumikiyo KAWAHARA, Kyoto (JP)

(21) Appl. No.: 19/076,215

(22) Filed: Mar. 11, 2025

Related U.S. Application Data
(63) Continuation of application No. PCT/JP2023/030499, filed on Aug. 24, 2023.

(30) Foreign Application Priority Data
Sep. 28, 2022 (JP) 2022-154577

(51) Int. Cl. G01R 31/3835; G01R 31/388; H01M 10/44; H02J 7/00

(52) U.S. Cl. CPC G01R 31/3835; G01R 31/388; H01M 10/44; H02J 7/0048; H02J 7/007182

(57) ABSTRACT

A battery characteristic acquisition system includes a charge control unit, a measuring unit, a storage unit, and a characteristic curve generating unit. The charge control unit charges a battery. The measuring unit measures an OCV before the start of charging of the battery and a charged capacity charged from the start of charging to the completion of charging to full charge, and calculates an SOC at the start of charging by subtracting the measured charged capacity from the full charge capacity of the secondary battery. The storage unit stores the OCV and the SOC obtained from a plurality of times of measurement and calculation. The characteristic curve generating unit generates an SOC-OCV curve of the battery using a plurality of OCVs and remaining capacities.

### CROSS REFERENCE TO RELATED APPLICATIONS

The present application is a continuation of PCT application no. PCT/JP2023/030499, filed on Aug. 24, 2023, which claims priority to Japanese patent application no. 2022-154577, filed on Sep. 28, 2022, the entire contents of which are incorporated herein by reference.

### BACKGROUND

The present disclosure relates to a technique of acquiring an SOC-OCV characteristic curve of a secondary battery.

A battery pack is described that calculates the degree of deterioration of a secondary battery. In the battery pack, an internal resistance of the secondary battery is calculated, and the increase rate of the internal resistance is calculated as the degree of deterioration of the secondary battery.

### SUMMARY

The present disclosure relates to a technique of acquiring an SOC-OCV characteristic curve of a secondary battery.

As further described in relation to the battery pack referenced in the Background section, in a method of obtaining the degree of deterioration of a secondary battery only from an internal resistance, only an index representing one of various deterioration factors of the secondary battery is obtained, and the state of deterioration of the secondary battery is not accurately obtained.

A known method capable of accurately obtaining the degree of deterioration of a secondary battery is a method using an SOC-OCV characteristic curve of a secondary battery.

However, a conventional method takes much time and effort to acquire an SOC-OCV characteristic curve of a secondary battery.

The present disclosure, in an embodiment, relates to easily acquire an SOC-OCV characteristic curve of a secondary battery.

A secondary battery characteristic acquisition system according to an embodiment of the present disclosure includes a charge control unit, a measuring unit, a storage unit, and a characteristic curve generating unit. The charge control unit has a first mode for intermittently charging a secondary battery and a second mode for continuously charging the secondary battery, and selects either the first mode or the second mode to charge the secondary battery. In the first mode, the measuring unit measures OCVs and capacities from the start of charging of the secondary battery, and calculates remaining capacities for each measured OCV. The storage unit stores OCVs and remaining capacities obtained from a plurality of times of measurement and calculation. The characteristic curve generating unit generates a remaining capacity-OCV curve of the secondary battery using the OCVs and remaining capacities obtained from a plurality of times of measurement and calculation. Furthermore, when OCVs for the capacity from 0% to 100% are finally acquired, the remaining capacities are converted to SOCs to complete an SOC-OCV curve.

The charge control unit, in an embodiment, performs charging in the first mode in a range where no terminal voltage and no SOC are stored, and performs charging in the second mode in a range where a terminal voltage and an SOC are stored.

In this configuration, in an embodiment, continuous charging is performed in a range where data for generating a characteristic curve (terminal voltage and SOC) is already measured or calculated, and intermittent charging is performed while measuring terminal voltages in a range where data for generating a characteristic curve (terminal voltage and SOC) is not yet measured or calculated. Accordingly, while much data for generating a characteristic curve is measured, the time it takes for each charging can be shortened. Thus, an SOC-OCV characteristic curve of a secondary battery can be easily acquired.

According to the present disclosure, in an embodiment, an SOC-OCV characteristic curve of a secondary battery can be easily acquired.

### BRIEF DESCRIPTION OF THE FIGURES

FIG. 1 is a functional block diagram illustrating a configuration of a battery characteristic acquisition system according to an embodiment of the present disclosure.

FIG. 2 is a flowchart illustrating an example of a secondary battery characteristic acquisition method according to an embodiment of the present disclosure.

FIG. 3 is a flowchart illustrating intermittent charging.

FIG. 4 is a chart illustrating an example of a relationship between SOC and performed charging of an embodiment.

FIG. 5 illustrates an example of an SOC-OCV curve of an embodiment.

FIG. 6 is a functional block diagram illustrating a configuration of a battery characteristic acquisition system according to an embodiment of the present disclosure.

FIG. 7 is a flowchart illustrating an example of a secondary battery characteristic acquisition method according to an embodiment of the present disclosure.

FIG. 8 is a chart illustrating an example of a relationship between SOC and performed charging of an embodiment.

FIG. 9 illustrates an example of an SOC-OCV curve of an embodiment.

### DETAILED DESCRIPTION

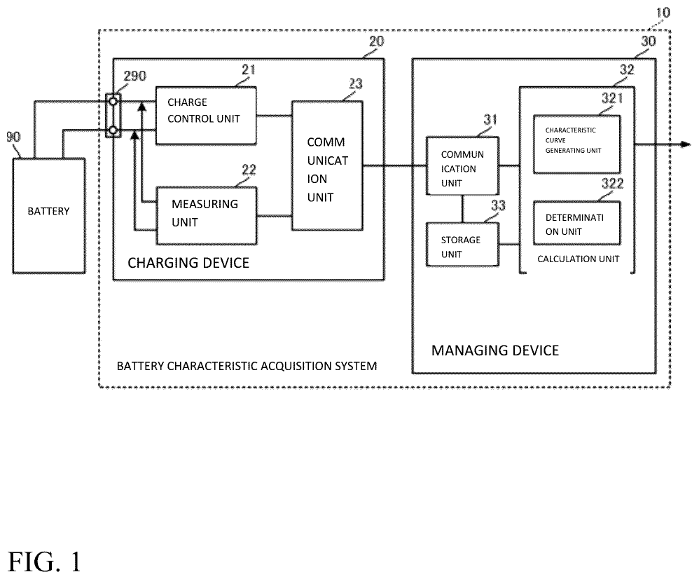

The present disclosure will be described in further detail below including with reference to the figures according to an embodiment. A secondary battery characteristic acquisition technique according to a first embodiment of the present disclosure will be described with reference to the drawings. FIG. 1 is a functional block diagram illustrating a configuration of a battery characteristic acquisition system according to the first embodiment of the present disclosure.

As illustrated in FIG. 1, a battery characteristic acquisition system 10 includes a charging device 20 and a managing device 30. The battery characteristic acquisition system 10 corresponds to “secondary battery characteristic acquisition system” of the present disclosure. This system is applied to, for example, a system for renting a device equipped with a battery (secondary battery) 90. In this case, the charging device 20 is provided in, for example, a rental agent that rents a device, and the managing device 30 is provided in, for example, a management company that manages rental of the device. Note that the present disclosure is not limited to a device equipped with the battery 90, and can also be applied to a rental system for the battery 90 alone.

The charging device 20 includes a charge control unit 21, a measuring unit 22, a communication unit 23, and a charge terminal 290. Although not illustrated, the charging device 20 is supplied with power from a commercial power source or the like.

The charge control unit 21 charges the battery 90 connected to the charge terminal 290. Specifically, the charge control unit 21 continuously supplies power until the battery 90 is charged to full charge according to a predetermined charging condition. During the charging, the charge control unit 21 acquires identification information (individual identification information) from the battery 90.

The measuring unit 22 measures a terminal voltage of the secondary battery. More specifically, the measuring unit 22 measures a voltage and an open circuit voltage (OCV) of the battery 90 being charged.

The measuring unit 22 measures a charged capacity charged from the start to completion of charging to full charge. More specifically, the measuring unit 22 measures a current from the start of charging to full charge and the time from the start of charging to full charge to calculate the charged capacity.

The measuring unit 22 calculates the SOC before charging by subtracting the charged capacity from the full charge capacity of the charged battery 90. The full charge capacity can be referred from, for example, the identification number of the battery 90 acquired by the charge control unit 21.

The communication unit 23 receives the identification number from the charge control unit 21, receives the OCV and the SCO from the measuring unit 22, associates the identification number of the battery 90, the OCV, and the SOC with each other, and transmits the identification number, the OCV, and the SOC to the communication unit 31 of the managing device 30.

The charge control unit 21 and the measuring unit 22 execute the processing described above each time the battery 90 is charged (each time a request for charging the battery 90 from a user is received). The communication unit 23 transmits the identification number of the battery 90, the OCV, and the SOC which are associated with each other.

The managing device 30 includes a communication unit 31, a calculation unit 32, and a storage unit 33.

The communication unit 31 receives the identification number of the battery 90, an OCV, and an SOC from the communication unit 23 of the charging device 20, and outputs the identification number, the OCV, and the SOC to the storage unit 33. Every time on receiving the identification number, the OCV, and the SOC, the communication unit 31 outputs the identification number, the OCV, and the SOC to the storage unit 33.

The storage unit 33 stores the identification number, the OCV, and the SOC that are output from the communication unit 31 and associated with each other. Every time data is input from the communication unit 31, the storage unit 33 sequentially stores the data. As a result, the storage unit 33 stores the identification number of the battery 90 and OCVs and SOCs obtained from a plurality of times of charging. That is, when a plurality of times of charging has been performed, the storage unit 33 stores OCVs and SOCs that are obtained from a plurality of times of charging in association with the identification number of the battery 90. The number of OCVs and SOCs to be stored corresponds to the number of times of charging.

The calculation unit 32 includes a characteristic curve generating unit 321 and a determination unit 322. The calculation unit 32 is achieved by, for example, a calculation processing device such as a personal computer.

The characteristic curve generating unit 321 calculates a characteristic curve of the battery 90 using the COVs and SOCs obtained from a plurality of times of charging. More specifically, the characteristic curve generating unit 321 calculates an SOC-OCV curve of the battery 90 using the OCVs and SOCs obtained from a plurality of times of charging. For example, the characteristic curve generating unit 321 may combine a method of estimating an OCV from a relaxation curve with calculation of an OCV.

A secondary battery characteristic acquisition technique using the configuration described above will be described with reference to the drawings. Schematically, in the secondary battery characteristic acquisition technique according to the present embodiment, while the charging device 20 charges the battery 90 a plurality of times, the managing device 30 calculates a remaining capacity-OCV curve using data obtained during charging of a plurality of times. If there is already a range in which a remaining capacity-OCV curve has been calculated, the charging device 20 and the managing device 30 do not acquire an OCV. Meanwhile, the charging device 20 and the managing device 30 additionally calculate a remaining capacity-OCV curve for a range (unmeasured range) different from a range for which the remaining capacity-OCV curve has already been calculated. The charging device 20 and the managing device 30 then combine these curves to calculate the whole remaining capacity-OCV curve.

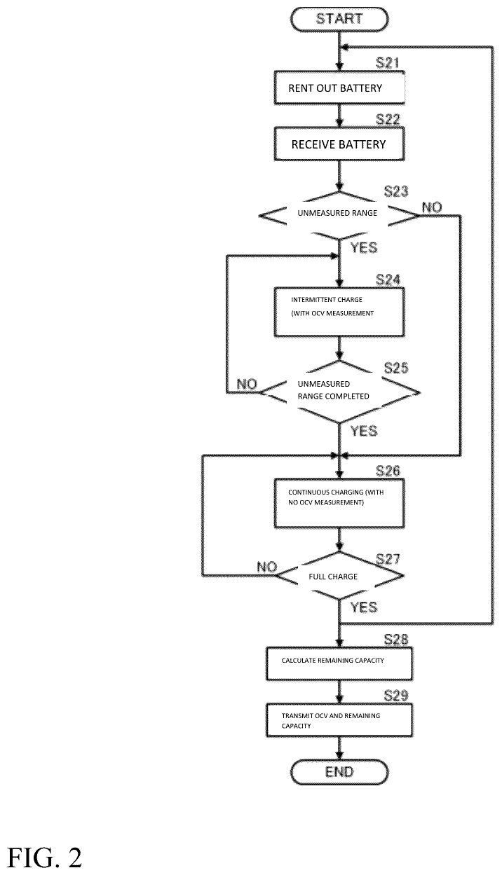

FIG. 2 is a flowchart illustrating an example of a secondary battery characteristic acquisition method according to the first embodiment of the present disclosure.

As illustrated in FIG. 2, an agency provided with the charging device 20 rents out a fully charged battery 90 to a user (S21), and receives a used battery 90 (S22).

The charging device 20 acquires an unmeasured range. The unmeasured range is a range in which no set of OCV and remaining capacity is stored. The charging device 20 determines whether a measured voltage at the start of charging for the current time, that is, the OCV for the current time is within the unmeasured range (S23).

Specifically, for the initial charging (first charging), the charging device 20 determines that the OCV of the current time, no matter what value, is within the unmeasured range.

For the second charging onward, when the state of the battery 90 at the time of return is within a range in which no set of OCV and remaining capacity is obtained in the past performed charging, the charging device 20 determines that the OCV is within the unmeasured range. That is, when the current OCV before the start of charging is lower than the stored minimum OCV, the charging device 20 determines that the OCV is within the unmeasured range.

Meanwhile, when the current remaining capacity is within a range in which the sets of OCV and remaining capacity are obtained in the past performed charging, the charging device 20 determines that the OCV is out of the unmeasured range (within an already measured range). That is, when the current OCV before the start of charging is equal to or higher than the stored minimum OCV, the charging device 20 determines that the OCV is out of the unmeasured range. Although the OCV cannot be directly measured while charging, the relationship between charge voltage and OCV is already known for the already measured range. Therefore, the OCV can be estimated from the charge voltage based on this relationship, and it can be determined that the OCV is out of the unmeasured range.

The charging device 20 (charge control unit 21) has a plurality of charging modes. More specifically, the charging device 20 has a first mode for intermittently charging the battery 90 and a second mode for continuously charging the battery 90.

In the unmeasured range (YES in S23), the charging device 20 performs charging in the first mode (intermittent charging) (S24).

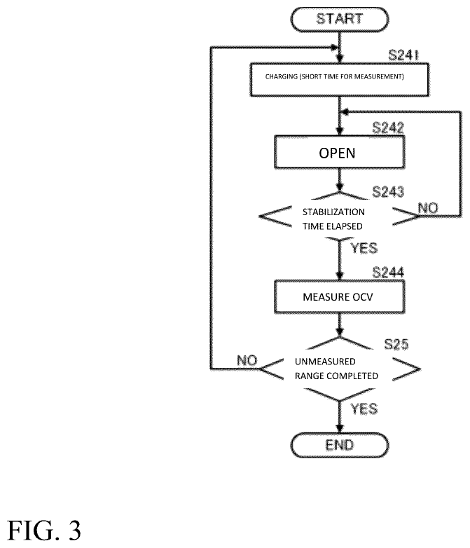

The charging in the first mode (intermittent charging) is specifically performed as follows. FIG. 3 is a flowchart illustrating intermittent charging.

The charging device 20 continuously performs charging in a short time for measurement (S241). The charging device 20 stops charging, electrically opens a terminal of the battery 90 (S242), and maintains the electrically opened state until a stabilization time (time it takes until the voltage shows no change, or stabilizes) elapses (NO in S243).

When the stabilization time has elapsed (YES in S243), the charging device 20 measures the opened terminal voltage (OCV) (S244).

The charging device 20 repeats (NO in S25) the short-time charging for measurement (S241), electrically opening the terminal (S242), and measuring OCV (S244) until data acquisition in the unmeasured range is completed. The completion of data acquisition in the unmeasured range can be known by detecting the OCV measured in S244 becoming equal to or higher than the previously measured OCV.

By performing such processing, the OCV can be measured while charging is performed little by little, so that many different sets of OCV and remaining capacity can be acquired.

When data acquisition in the unmeasured range is completed (YES in S25), the charging device 20 performs charging in the second mode (continuous charging) (S26). In this charging, the charging device 20 does not perform measurement of OCV.

The charging device 20 performs charging in the second mode (continuous charging) described above (S26) until full charge is established (NO in S27).

When full charge is established (YES in S27), the charging device 20 calculates the remaining capacity for each measured OCV (S28), associates sets of OCV and remaining capacity with the identification information of the battery 90, and transmits the associated sets to the managing device 30 (S29).

The managing device 30 calculates a remaining capacity-OCV curve of the battery 90 using a plurality of sets of OCV and remaining capacity received from the charging device 20 and stored. Further, the managing device 30 calculates an SOC-OCV curve of the battery 90 using SOCs calculated from the capacity and remaining capacities of the battery 90.

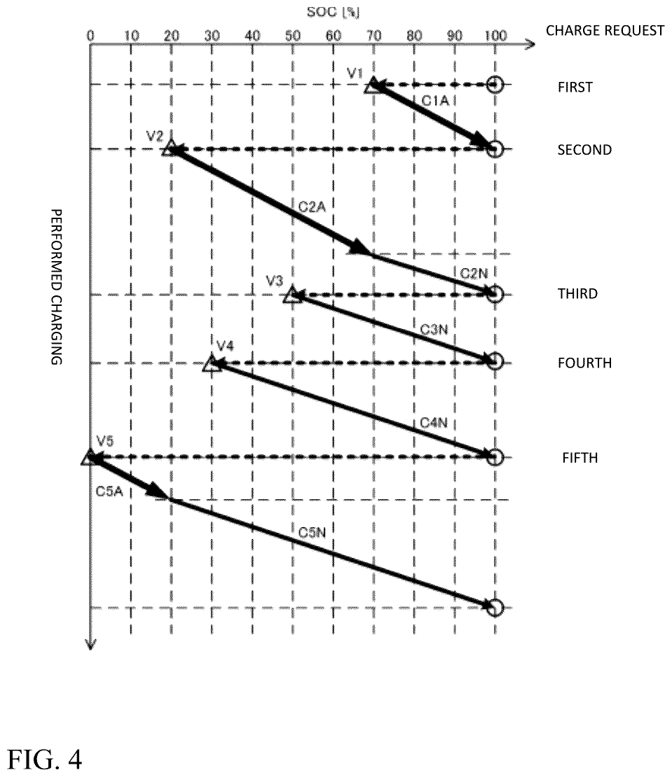

FIG. 4 is a chart illustrating an example of a relationship between SOCs and performed charging in the first embodiment. In FIG. 4, until enough data is collected, SOCs cannot be calculated because the full charge capacity is not known, so that remaining capacity data is accumulated. For simplicity of description, the horizontal axis represents SOC, and the vertical axis represents performed charging. A circle indicates a full charge state, and a triangle indicates an SOC before the start of charging. Voltages V1 to V5 appended to the triangles each indicate the OCV at each time. C1A, C2A, and C5A represent charged capacities by intermittent charging, and C2N, C3N, C4N, and C5N represent charged capacities by continuous charging.

In the first charging, there is no stored set of OCV and remaining capacity. Therefore, in the first charging, the entire range to be charged is an unmeasured range. The charging device 20 measures an OCV (V1) before the start of charging, and performs intermittent charging while measuring OCVs in the first mode. When full charge is established, the charging device 20 calculates a charged capacity CIA and calculates the remaining capacity at each OCV.

In the first charging, sets of SOC and OCV can be acquired in a short time cycle for measurement for a range from SOC 70% to SOC 100%.

In the second charging, the range from SOC 70% to SOC 100% is an already measured range, and a range in which SOC is lower than 70% (a range in which OCV is lower than V1) is an unmeasured range.

The charging device 20 measures an OCV (V2) before the start of charging, and determines that the OCV is within the unmeasured range because V2 is lower than V1. Therefore, in the second charging, the charging device 20 first performs intermittent charging and measuring of OCV in the first mode.

The charging device 20 performs intermittent charging in the first mode, and when detecting that data acquisition in the unmeasured range is completed switches from the first mode to the second mode, and performs continuous charging without measuring OCV. That is, the charging device 20 performs intermittent charging in the first mode, switches from the first mode to the second mode when OCV reaches V1 (when SOC reaches 70%), and performs continuous charging without measuring OCV. Charging in the second mode can be performed at a higher speed than in the first mode also under the same charge voltage and charge current as the first mode since opening of the terminal, a process of letting the stabilization time elapse, and measuring of OCV are not performed.

Thereafter, when full charge is established, the charging device 20 calculates a charged capacity C2A in the first mode (intermittent charging) and a charged capacity C2N in the second mode (continuous charging), and calculates the remaining capacity at each OCV obtained in the first mode.

In the second charging, sets of remaining capacity and OCV can be acquired in a short time cycle for measurement in a range from SOC 20% to SOC 70%.

In the third charging, the range from SOC 20% to SOC 100% is an already measured range, and a range in which SOC is lower than 20% (a range in which OCV is lower than V2) is an unmeasured range.

The charging device 20 measures an OCV (V3) before the start of charging, and determines that the OCV is out of the unmeasured range because V3 is higher than V2. Therefore, in the third charging, the charging device 20 performs continuous charging in the second mode until full charge is established.

In the fourth charging, the range from SOC 20% to SOC 100% is the already measured range as in the third charging, and the range in which SOC is lower than 20% (a range in which OCV is lower than V2) is the unmeasured range.

The charging device 20 measures an OCV (V4) before the start of charging, and determines that the OCV is out of the unmeasured range because V4 is higher than V2. Therefore, in the fourth charging, the charging device 20 performs continuous charging in the second mode until full charge is established.

In the fifth charging, the range from SOC 20% to SOC 100% is the already measured range as in the third charging and the fourth charging, and the range in which SOC is lower than 10% (a range in which OCV is lower than V2) is the unmeasured range.

The charging device 20 measures an OCV (V5) before the start of charging, and determines that the OCV is within the unmeasured range because V5 is lower than V2. Therefore, in the fifth charging, the charging device 20 first performs intermittent charging while measuring OCV in the first mode.

The charging device 20 performs intermittent charging in the first mode, and when detecting that data acquisition in the unmeasured range is completed switches from the first mode to the second mode, and performs continuous charging without measuring OCV. That is, the charging device 20 performs intermittent charging in the first mode, switches from the first mode to the second mode when OCV reaches V2 (when SOC reaches 20%), and performs continuous charging without measuring OCV.

Thereafter, when full charge is established, the charging device 20 calculates the charged capacity C5A in the first mode (intermittent charging) and the charged capacity C5N in the second mode (continuous charging), and calculates the remaining capacity at each OCV obtained in the first mode.

In the fifth charging, sets of remaining capacity and OCV can be acquired in a short time cycle for measurement in the range from SOC 0% to SOC 20%.

Then, by performing the processing described above, OCVs are acquired and SOCs can be calculated from the full charge capacity and the remaining capacities for a range from SOC 0% to SOC 100% (full charge) through a plurality of times of charging (charge requests), that is, a total of five times of charging.

By performing such processing, the managing device 30 can obtain data of the following sets of SOC and OCV.

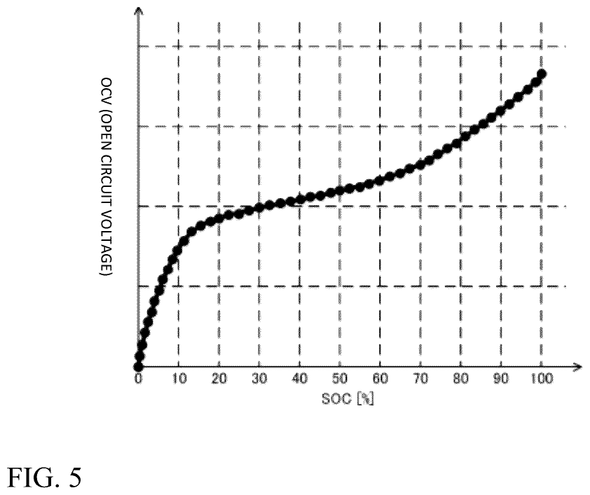

FIG. 5 illustrates an example of a remaining capacity-OCV curve of the first embodiment. In FIG. 5, the horizontal axis represents SOC and the vertical axis represents OCV. Each black circle in FIG. 5 is measurement data of OCV and SOC as illustrated in FIG. 4.

As indicated by the black circles in FIG. 5, SOCs and OCVs can be acquired at fine intervals during intermittent charging. As a result, the managing device 30 can further accurately calculate an SOC-OCV curve.

In addition, using the method of the first embodiment allows acquiring, in the second charging and onward, sets of SOC and OCV at fine intervals only in a range in which a set of SOC and OCV is not yet acquired. As a result, charging can be performed at a higher speed in a range in which sets of SOC and OCV have already been obtained. Therefore, the battery characteristic acquisition system 10 can calculate an SOC-OCV curve more accurately while suppressing the charging time of the battery 90 becoming undesirably long.

A secondary battery characteristic acquisition technique according to a second embodiment of the present disclosure will be described with reference to the drawings. The secondary battery characteristic acquisition technique according to the second embodiment is different from the secondary battery characteristic acquisition technique according to the first embodiment in that, under a specific condition, OCV and SOC are measured after discharging. Hereinafter, only different portions will be described.

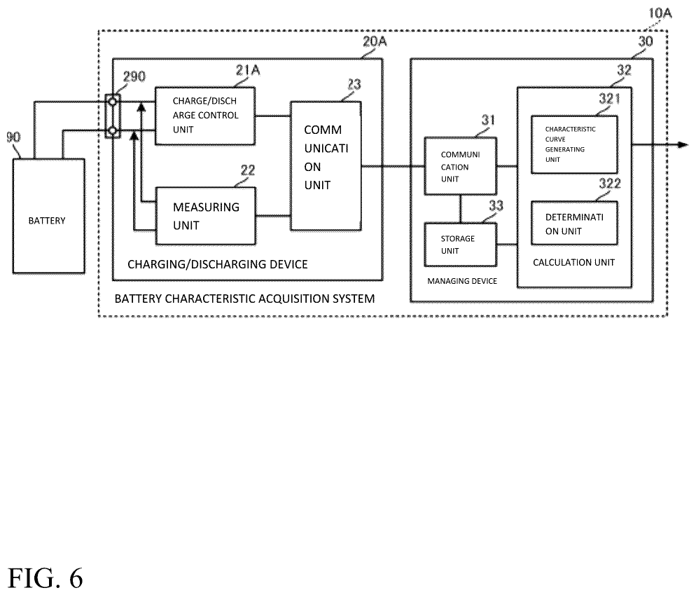

FIG. 6 is a functional block diagram illustrating a configuration of a battery characteristic acquisition system according to the second embodiment of the present disclosure. As illustrated in FIG. 6, a battery characteristic acquisition system 10A is different from the battery characteristic acquisition system 10 according to the first embodiment in that a charging/discharging device 20A is included. The charging/discharging device 20A includes a charge/discharge control unit 21A.

The charge/discharge control unit 21A having a function (charge function) of the charge control unit 21 illustrated in the first embodiment further has a discharge function. That is, the charge/discharge control unit 21A can control discharging as well as charging of a battery 90.

When a set of SOC and OCV is measured and when a specific condition is satisfied, the charge/discharge control unit 21A performs, after performing discharging, intermittent charging in the first mode in an SOC range in which discharging has been performed.

A managing device 30 calculates an SOC-OCV curve of the battery 90 using the sets of remaining capacity and OCV obtained by a measuring unit 22 from a plurality of times of charging during charging and charging after discharging performed by the charge/discharge control unit 21A.

In the above description, intermittent charging is performed in the first mode after discharging is performed, but intermittent discharging may be performed in the first mode in the same section to measure OCVs.

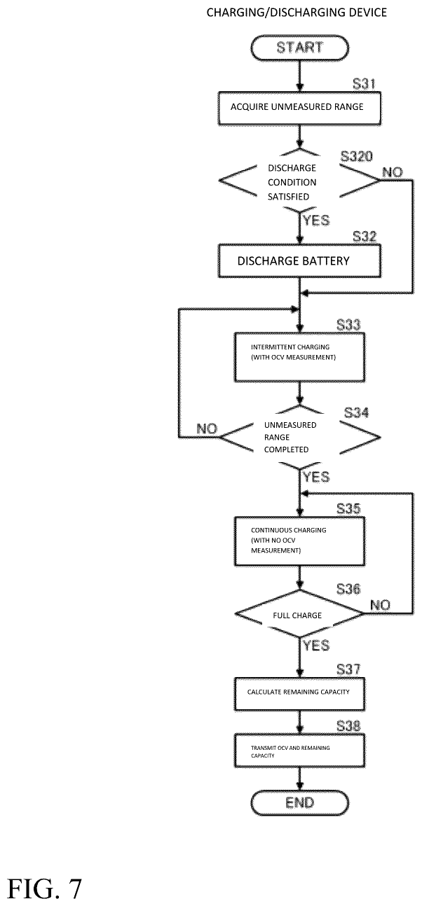

FIG. 7 is a flowchart illustrating an example of a secondary battery characteristic acquisition method according to the second embodiment of the present disclosure. In FIG. 7, description of a charge control with no discharge control is omitted, where the charge control with no discharge control added is similar to that of the first embodiment.

The charging/discharging device 20A acquires an unmeasured range from the managing device 30 (S31).

The charging/discharging device 20A measures the OCV before the start of charging of the battery 90 for which charge request is made. When a discharge condition is satisfied (YES in S320), the charging/discharging device 20A causes the battery 90 to discharge (S32).

Here, the discharge condition is one or both of a condition that the number of times of charging (the number of charge requests) reaches a predetermined number and a condition that the OCV before the start of charging is equal to or lower than a discharge-allowed voltage. For example, when the discharge condition is the number of times of charging, the discharge condition is set to four times of charging. When the discharge condition is the discharge-allowed voltage, the discharge condition is set to an OCV corresponding to the OCV before the start of charging of SOC 20%. Furthermore, when the discharge condition is the number of times of charging and the discharge-allowed voltage, the discharge condition is set to four or more times of charging and an OCV corresponding to the OCV before the start of charging of SOC 20%. Note that, this is an example, and the present disclosure is not limited thereto.

The charging/discharging device 20A reduces the SOC to 0% by discharging, and then performs intermittent charging in the first mode in an unmeasured range (S33). Alternatively, the charging/discharging device 20A acquires data down to SOC 0% during intermittent discharging in the first mode.

The charging/discharging device 20A continues intermittent charging in the first mode (S33) until data acquisition in the unmeasured range is completed (NO in S34).

When data acquisition in the unmeasured range is completed (YES in S34), the charging/discharging device 20A performs charging in the second mode (continuous charging) (S35). The charging/discharging device 20A performs charging in the second mode (continuous charging) described above (S35) until full charge is established (NO in S36).

When full charge is established (YES in S36), the charging/discharging device 20A calculates the remaining capacity for each measured OCV (S37), associates sets of OCV and remaining capacity with identification information of the battery 90, and transmits the associated sets to the managing device 30 (S38).

The managing device 30 calculates an SOC-OCV curve of the battery 90 using a plurality of sets of OCV and remaining capacity received from the charging device 20 and stored.

By this configuration and processing, the battery characteristic acquisition system 10A can forcibly acquire, by performing discharging, a set of SOC and OCV not acquired in the past performed charging. By setting the discharge condition described above, the battery characteristic acquisition system 10A performs discharging not unconditionally but only when a specific condition is satisfied, so that deterioration of the battery 90 due to discharging can be suppressed.

In particular, by performing discharging only in a range where SOC is low, the battery characteristic acquisition system 10A can further suppress deterioration of the battery 90 due to discharging.

In addition, by setting the discharge condition to the number of times of charging, the battery characteristic acquisition system 10A can avoid a continuing state of no set of remaining capacity and OCV being acquired, and can more reliably calculate an accurate remaining capacity-OCV curve.

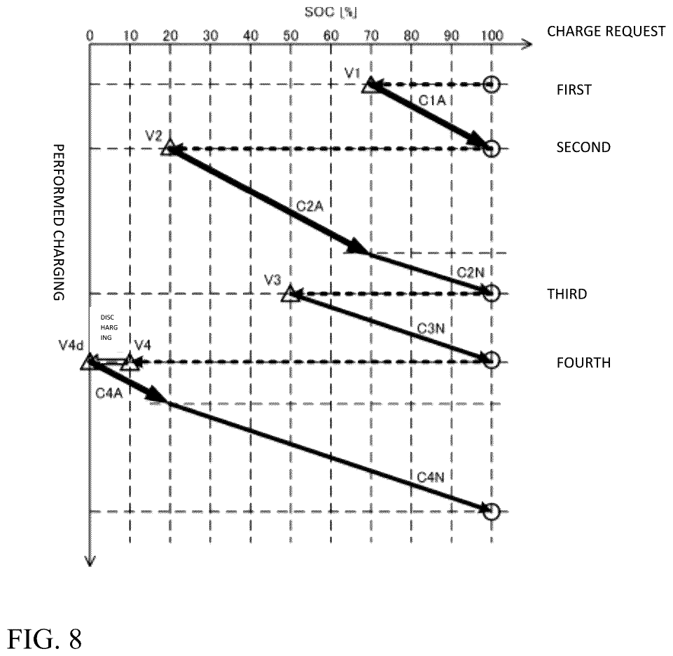

FIG. 8 is a chart illustrating an example of a relationship between SOC and performed charging of the second embodiment. In FIG. 8, the horizontal axis represents SOC and the vertical axis represents performed charging. A circle indicates a state of full charge, and a triangle indicates the SOC before the start of charging. Voltages V1 to V4 and V4d appended to the triangles each indicate the OCV at each time. C1A, C2A, and C4A represent charged capacities by intermittent charging, and C2N, C3N, and CAN represent charged capacities by continuous charging.

The first charging, the second charging, and the third charging are similar to those of the first embodiment described above (see FIG. 4), and description thereof is omitted.

In the fourth charging, the range from SOC 20% to SOC 100% is an already measured range as in the third charging, and a range in which SOC is lower than 20% (a range in which OCV is lower than V2) is an unmeasured range.

The charging/discharging device 20A measures an OCV (V4) before the start of charging, and determines that the OCV is within the unmeasured range because V4 is lower than V2. Furthermore, since the fourth charging satisfies a discharge condition (for example, when the number of times of charging is four and an OCV is lower than the OCV of the SOC 20%), the charging/discharging device 20A causes the battery 90 to discharge.

The charging/discharging device 20A measures an OCV (V4d) after discharging to SOC 0%. The charging/discharging device 20A then first performs intermittent charging and measuring of OCV in the first mode.

The charging/discharging device 20A performs intermittent charging in the first mode, and when detecting that data acquisition in the unmeasured range is completed switches from the first mode to the second mode, and performs continuous charging without measuring OCV. That is, the charging/discharging device 20A performs intermittent charging in the first mode, switches from the first mode to the second mode when OCV reaches V2 (when SOC reaches 20%), and performs continuous charging without measuring OCV.

Thereafter, when full charge is established, the charging/discharging device 20A calculates the charged capacity C4A in the first mode (intermittent charging) and the charged capacity CAN in the second mode (continuous charging), and calculates the SOC at each OCV obtained in the first mode.

In the fourth charging, discharging is performed and sets of SOC and OCV can be acquired for a short time cycle for measurement for a range from SOC 0% to SOC 20%.

Thus, the battery characteristic acquisition system 10A can effectively use discharge processing to acquire sets of SOC and OCV for a range from SOC 0% to SOC 100% (full charge) in a short time cycle for measurement.

By performing such processing, the managing device 30 can obtain data of the following sets of SOC and OCV.

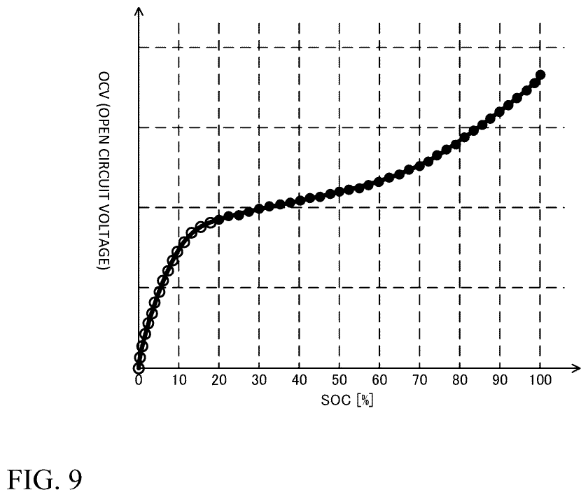

FIG. 9 illustrates an example of an SOC-OCV curve in the second embodiment. In FIG. 9, the horizontal axis represents SOC and the vertical axis represents OCV. White circles and black circles in FIG. 9 are measurement data of OCV and SOC. The white circles are measurement data obtained using discharging. The black circles are measurement data obtained not using discharging (measurement data obtained by a method similar to that in the first embodiment).

As indicated by the white circles and the black circles in FIG. 9, SOCs and OCVs can be acquired at fine intervals from SOC 0% to SOC 100%. As a result, the managing device 30 can further accurately calculate an SOC-OCV curve.

In addition, using the method of the second embodiment, the battery characteristic acquisition system 10A can acquire sets of SOC and OCV using discharging for a range in which data was not acquired during a plurality of times of charging with no discharging. Therefore, the battery characteristic acquisition system 10A can calculate an SOC-OCV curve more accurately while suppressing the number of times of charging of the battery 90 becoming very large.

In addition, by setting the OCV corresponding to the SOC allowing discharging to a low value, the battery characteristic acquisition system 10A can suppress deterioration of the battery 90 due to discharging.

### DESCRIPTION OF REFERENCE SYMBOLS

10, 10A: Battery characteristic acquisition system
20: Charging device
20A: Charging/discharging device
21: Charge control unit
21A: Charge/discharge control unit
22: Measuring unit
23: Communication unit
30: Managing device
31: Communication unit
32: Calculation unit
33: Storage unit
90: Battery
290: Charge terminal
321: Characteristic curve generating unit
322: Determination unit

It should be understood that various changes and modifications to the embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A secondary battery characteristic acquisition system comprising:
a charge control unit that has a first mode for intermittently charging a secondary battery and a second mode for continuously charging the secondary battery, and selects one of the first mode and the second mode to charge the secondary battery;
a measuring unit that measures, in the first mode, a terminal voltage of the secondary battery and calculates a remaining capacity for each terminal voltage that has been measured;
a storage unit that stores a plurality of the terminal voltages and the remaining capacities obtained from a plurality of times of measurement and calculation; and
a characteristic curve generating unit that generates a remaining capacity-OCV curve of the secondary battery using the plurality of the terminal voltages and the remaining capacities obtained from the plurality of times of measurement and calculation,
wherein the charge control unit
performs charging in the first mode in a range in which the terminal voltage and the remaining capacity are not stored, and
performs charging in the second mode in a range in which the terminal voltage and the remaining capacity are stored.

2. The secondary battery characteristic acquisition system according to claim 1, further comprising a charge/discharge control unit that includes the charge control unit and performs charge control and discharge control,
wherein the charge/discharge control unit performs, when there is an unmeasured range in which the terminal voltage and the remaining capacity are not measured and a discharge-allowing condition is satisfied, discharging of the secondary battery and then performs charging in the first mode for the unmeasured range.

3. The secondary battery characteristic acquisition system according to claim 2, wherein the discharge-allowing condition is that a terminal voltage before start of charging is equal to or lower than a voltage allowing discharging.

4. A secondary battery characteristic acquisition method comprising:
a charge controlling step of selecting one of a first mode for intermittently charging a secondary battery and a second mode for continuously charging the secondary battery to charge the secondary battery;
a measuring step of measuring, in the first mode, a terminal voltage of the secondary battery and calculating a remaining capacity for each terminal voltage that has been measured;
a storing step of storing a plurality of the terminal voltages and the remaining capacities obtained from a plurality of times of measurement and calculation; and
a characteristic curve calculating step of generating a remaining capacity-OCV curve of the secondary battery using the plurality of the terminal voltages and the remaining capacities obtained from the plurality of times of measurement and calculation,
wherein the charge controlling step includes
performing charging in the first mode in a range in which the terminal voltage and the remaining capacity are not stored, and
performing charging in the second mode in a range in which the terminal voltage and the remaining capacity are stored.

5. The secondary battery characteristic acquisition method according to claim 4, further comprising a charge/discharge controlling step that includes the charge controlling step and performing charge control and discharge control,
wherein the charge/discharge controlling step includes performing, when there is an unmeasured range in which the terminal voltage and the remaining capacity are not measured and a discharge-allowing condition is satisfied, discharging of the secondary battery and then performing charging in the first mode for the unmeasured range.

6. The secondary battery characteristic acquisition method according to claim 5, wherein the discharge-allowing condition is that a terminal voltage before start of charging is equal to or lower than a voltage allowing discharging.
